(19) United States
(12) Patent Application Publication
(10) Pub. No.: US 2011/0230020 A1
(43) Pub. Date: Sep. 22, 2011

(54) SCHOTTKY-BARRIER MOS TRANSISTOR ON A FULLY-DEPLETED SEMICONDUCTOR FILM AND PROCESS FOR FABRICATING SUCH A TRANSISTOR

(75) Inventors: Thomas SKOTNICKI, Crolles-Montfort (FR); Stéphane MONFRAY, Grenoble (FR)

(73) Assignee: STMicroelectronics (Crolles2) SAS, Crolles (FR)

(21) Appl. No.: 13/150,511

(22) Filed: Jun. 1, 2011

Related U.S. Application Data
(62) Division of application No. 11/672,193, filed on Feb. 7, 2007.

(30) Foreign Application Priority Data
Feb. 5, 2007 (FR) 0601137

(51) Int. Cl. H01L 21/336

(52) U.S. Cl. 438/164; 257/E21.411

(57) ABSTRACT

This process for manufacturing a Schottky-barrier MOS transistor on a fully depleted semiconductor film may include depositing a first layer of a first sacrificial material on an active zone of the substrate, forming a silicon layer on top of the first layer of sacrificial material, forming a gate region on top of the silicon layer with interposition of a gate oxide layer, and selective etching of the sacrificial material so as to form a tunnel beneath the gate region. The tunnel is filled with a dielectric second sacrificial material. A controlled lateral etching of the second sacrificial material is performed so as to keep behind a zone of dielectric material beneath the gate region. Silicidation is performed at the location of the source region and drain region and at the location of the etched zone.

### FIELD OF THE INVENTION

The invention relates to the production of MOS transistors, and in particular, to the production of Schottky-barrier MOS (SBMOS) transistors.

### BACKGROUND OF THE INVENTION

Schottky-barrier MOS transistors are readily known by those skilled in the art. Compared with conventional transistors in which the source and drain regions are produced by locally doping the silicon at the location of the source and drain regions, and by covering the doped regions with a silicide layer to form electrical contact zones and to reduce the access resistances at these contacts, SBMOS transistors are based on the production of source and drain regions in the form of conventionally formed Schottky-barrier contact zones made of a metal silicide.

In other words, the doped regions are replaced with a metal silicide so as to form, between the source and drain regions, metal/semiconductor transitions between the source and drain regions. Such an architecture helps to alleviate the drawbacks associated with conventional transistors and, in particular, to obtain an increase in current and to increase the switching speed of transistors by lowering the parasitic capacitance and resistance values.

SBMOS transistors are also advantageous because they do not require source and drain extensions by ion implantation. The silicide itself may be used to define the desired junctions. However, SBMOS transistors may have a major drawback. This is because they use lateral extensions of the silicided regions up to a point just beneath the gate region, so that the gate region partially covers the silicided regions. This constraint requires the provision of lateral silicidation during the fabrication process for SBMOS transistors.

Specifically, in order to modulate the potential barrier between the source and drain regions, the metal/semiconductor junction is to be placed beneath the gate. Now, lateral silicidation is necessarily accompanied by depthwise consumption of silicon. Moreover, there is a risk of forming holes because of the migration of silicon atoms into the channel during silicidation. Furthermore, lateral silicidation is incompatible with the production of SBMOS transistors on thin silicon films.

### SUMMARY OF THE INVENTION

In view of the foregoing, an object of the invention is to alleviate the drawbacks associated with the production of conventional Schottky-barrier transistors.

This an other objects, features and advantages in accordance with the invention are provided by a process for manufacturing a Schottky-barrier MOS transistor on a fully depleted semiconductor film comprising depositing a first layer of a first sacrificial material on an active zone of the substrate, with the active zone being bounded by an isolating region (STI).

The method may further comprise forming a silicon layer on top of the first layer of sacrificial material, producing a gate region on the silicon layer with interposition of a gate oxide layer between the silicon layer and the gate region, and selective etching of the first sacrificial material so as to form a tunnel beneath the gate region. The tunnel may be filled with a dielectric second sacrificial material. The method may further comprise a controlled lateral etching of the second sacrificial material so as to keep behind a zone of dielectric material beneath the gate region, and silicidation at the location of the source region and drain region and at the location of the etched zone of the second sacrificial material.

Thus, it is possible to form SBMOS transistors on a thin silicon film of the FDSOI (fully-depleted silicon-on-insulator) type with a thickness on the order of 10 nm. In one method of implementing the process according to the invention, the silicidation step comprises the deposition of a metal at the location of the source and drain regions so as to fill the etched zone of the second material.

The metal may be platinum or erbium, depending on the height of the barrier to be obtained. The first sacrificial material may be silicon-germanium, for example. With regards to the second sacrificial material, an oxide/nitride mixture may be used, for example.

Another aspect of the invention is directed to a Schottky-barrier MOS (SBMOS) transistor of the type comprising a substrate in which there are formed an active region, bounded by an isolating region, source and drain regions and a gate region that is formed in the active zone. The gate region extends between the source and drain regions. The source and drain regions may comprise metal silicide.

The transistor may be formed on a fully-depleted semiconductor film that defines a conduction channel for the transistor and forms, with the source and drain regions, metal/semiconductor transitions. The metallic material making up the source and drain regions extends to a point just beneath the gate region. The metal silicide may be platinum silicide, for example. As a variation, an erbium silicide may be used.

The semiconductor film may be a single-crystal silicon film that extends beneath the source and drain regions and forms, together with the metal silicide, the Schottky junction for the transistor. The transistor may furthermore include a layer of sacrificial dielectric material that extends between the source and drain regions beneath the single-crystal silicon layer.

### BRIEF DESCRIPTION OF THE DRAWINGS

Other objects, features and advantages of the invention will become apparent on reading the following description, which is given by way of non-limiting examples and with reference to the appended drawings in which:

FIG. 1 illustrates schematically the structure of an SBMOS transistor according to the invention; and

FIGS. 2 to 7 illustrate the main phases of the process for fabricating the SBMOS transistor of FIG. 1.

### DETAILED DESCRIPTION OF THE PREFERRED EMBODIMENTS

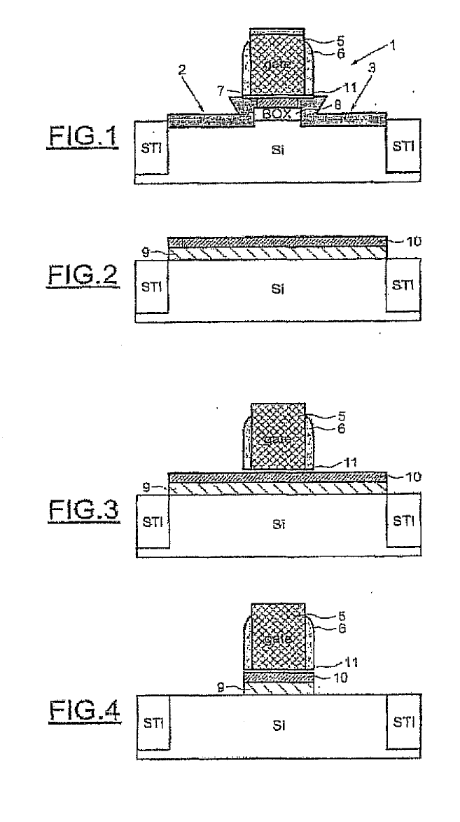

FIG. 1 shows schematically the general structure of an SBMOS transistor 1 according to the invention. This transistor is produced in an active zone of a silicon substrate Si. The active zone is bounded by a shallow trench isolation region STI, by the formation of a source region 2 and a drain region 3 and the formation of a gate region 5 associated with spacers 6, so that the gate region extends on top of a conduction channel 7 that lies between the source region 2 and drain region 3.

In the SBMOS transistor 1, the source and drain regions 2 and 3 are made of metal so as to create, between the source and drain regions, a Schottky barrier generated by the existence of metal/semiconductor junctions between the source and drain regions 2 and 3. The source and drain regions are made of a metal silicide.

As will be understood, the height of the barrier thus formed depends on the material used for producing the source and drain regions. Thus, for example, a platinum silicide will be used to form a barrier of about 0.3 volts for the production of pMOS transistors, whereas an erbium silicide will be used to create a barrier of about 0.28 volts for the production of nMOS transistors.

As shown in FIG. 1, the silicided regions 2 and 3 extend laterally beyond the spacers 6 up to a point beneath the gate, so that the gate 5 overlaps part of the silicided regions. It may also be seen in FIG. 1 that the gate region 5 is formed on a gate oxide layer on top of a semiconductor material layer 7 forming the conduction channel. In this case single-crystal silicon, which is itself formed on part of a buried oxide (BOX) layer 8 lies on either side of the silicided regions 2 and 3.

Thus, beneath the gate there are metal/semiconductor junctions that make it possible, as indicated above, to achieve advantageous levels of performance, especially in regards to current gain and switching rate compared with conventional transistors in which the source and drain regions are formed by doping the silicon substrate, for the purpose of reducing the parasitic capacitance and resistance values.

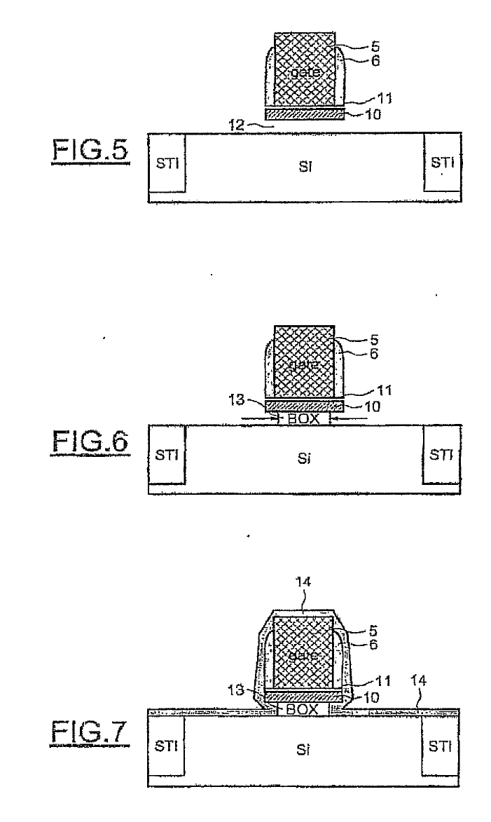

A process for fabricating such a transistor will now be described with reference to FIGS. 2 to 7. Referring first to FIG. 2, it is necessary to first grow, by selective epitaxy, a layer of a first sacrificial material 9 on the active zone of a silicon Si substrate bounded by the shallow trench isolation region STI. For example, the substrate Si is an n-type substrate or a p-type substrate, depending on the type of SBMOS transistor to be produced.

Preferably, the first sacrificial material comprises silicon-germanium, which can be selectively etched relative to silicon. After the silicon-germanium layer 9 has been deposited, a single-crystal silicon layer 10 is deposited on the active zone of the Si substrate so as to cover the subjacent silicon-germanium layer 9.

Referring to FIG. 3, during the next step the gate region 5 is produced with the interposition of the gate oxide layer 11, by deposition of a gate material layer on the gate oxide layer 11, followed by etching of the gate. The spacer 6 is then formed by deposition of a spacer material and the etching of the spacers. During the next step, referring to FIG. 4, the source and drain regions are anisotropically etched, by etching the silicon layer 10 and the silicon-germanium layer 9 at the location of the source and drain regions.

Next, the silicon-germanium undergoes selective etching. During this step, the silicon-germanium is removed laterally so as to form a tunnel 12 beneath both the gate 5 and the spacers G. The structure thus produced is then in the configuration shown in FIG. 5. In this configuration, the gate, the gate oxide and the localized silicon zone 10 form a bridge on top of the silicon. The bridge lies laterally, on both sides, with respect to the peripheral isolating region STI. During the next step, the space left bare is filled with a dielectric 13 (FIG. 6). For example, an oxide/nitride mixture is used. However, it should be noted that it would not be outside the scope of the invention if another type of dielectric that can be selectively etched by isotropic etching were to be used.

Next, lateral isotropic etching of the dielectric 13 is carried out. During this step, the dielectric 13 is etched laterally beyond the spacers 6 up to a point just below the gate region 5. To do this, the etching time is controlled, in a known manner, so as to leave behind only a dielectric zone 13 located beneath the gate region 5.

During the next step, with reference to FIG. 7, metal, for example erbium or platinum, is deposited over the entire structure, including the gate and the source and drain regions. This deposition of a metal layer 14 is then followed by an actual silicidation step, in particular by heating to a temperature of about 400 to 500° C.

As a result of the step of depositing the dielectric layer and the step of laterally etching this dielectric layer, beyond the spacers, the silicided regions extend up to a point just beneath the gate. Thus, the metal/semiconductor junctions are vertically in line with the gate.

It should also be noted that a very thin silicon layer 7 is used. The thickness of this layer may thus be on the order of ten nanometers. Likewise, the layer of dielectric material 8 is also very thin. Thus, the distance between the silicon channel 7 and the silicon substrate Si is very short. Furthermore, according to one feature, the silicon film 7 is formed by an undoped film.

Following the silicidation step is a step for the selective removal of the deposited metal that has not been silicided, in particular at the location of the isolating region STI and of the spacers 6. What is therefore obtained is the structure illustrated in FIG. 1.

Finally, it should be noted that the invention, which uses lateral etching of a sacrificial material on which a gate has been formed, with interposition of a silicon layer 10, makes it possible to provide a number of advantages. First, the end zones of the silicon channel 7 are accessible, so that the silicidation may be carried out at no risk of lateral silicon diffusion. Second, it is possible to use thin silicide layers. Third, as indicated above, the final structure makes it possible to combine the advantages associated with the use of a thin film and that of metal junctions.

1-12. (canceled)

13. A process for manufacturing a Schottky-barrier MOS transistor on a semiconductor substrate comprising an active zone bounded by an isolating region, the process comprising:
forming a first sacrificial layer on the active zone of the semiconductor substrate;
forming a silicon layer on the first sacrificial layer;
forming a gate oxide layer on the silicon layer;
forming a gate on the gate oxide layer;
forming a tunnel beneath the gate by selective etching of the first sacrificial layer;
filling the tunnel with a dielectric second sacrificial material;
laterally etching the dielectric second sacrificial material so as to keep behind a zone of dielectric second sacrificial material beneath the gate; and
forming silicide at a location of source and drain regions of the MOS transistor and at a location of the etched zone of the dielectric second sacrificial material.

14. A process according to claim 13, wherein forming silicide comprises depositing metal at the location of the source and drain regions so as to fill the etched zone of the dielectric second sacrificial material.

15. A process according to claim 14, wherein the metal comprises platinum.

16. A process according to claim 14, wherein the metal comprises erbium.

17. A process according to claim 13, wherein the first sacrificial layer comprises silicon-germanium.

18. A process according to claim 13, wherein the dielectric second sacrificial material comprises an oxide nitride mixture.

19. A process for manufacturing a Schottky-barrier MOS transistor comprising:
forming a first sacrificial layer on an active zone of a semiconductor substrate;
forming a silicon layer on the first sacrificial layer;
forming a gate region on the silicon layer;
forming a tunnel beneath the gate region by selective etching of the first sacrificial layer;
filling the tunnel with a dielectric material;
laterally removing a portion of the dielectric material so as to keep behind a zone of dielectric material beneath the gate region; and
forming silicide at a location of source and drain regions of the MOS transistor and at a location of the removed zone of the dielectric material.

20. A process according to claim 19, wherein forming silicide comprises depositing metal at the location of the source and drain regions so as to fill the etched zone of the dielectric material.

21. A process according to claim 20, wherein the metal comprises platinum.

22. A process according to claim 20, wherein the metal comprises erbium.

23. A process according to claim 19, wherein the first sacrificial layer comprises silicon-germanium.

24. A process according to claim 19, wherein the dielectric material comprises an oxide nitride mixture.

25-35. (canceled)
